(19) United States
(12) Patent Application Publication
(10) Pub. No.: US 2025/0160197 A1
(43) Pub. Date: May 15, 2025

(54) LIGHT-EMITTING ELEMENT AND DISPLAY DEVICE

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/931,515

(22) Filed: Oct. 30, 2024

(30) Foreign Application Priority Data
Nov. 10, 2023 (JP) 2023-192081

(51) Int. Cl. H10K 85/60; C09K 11/02; C09K 11/06; H10K 101/10; H10K 101/20; H10K 101/30; H10K 101/70

(52) U.S. Cl. CPC H10K 85/60; C09K 11/02; C09K 11/06; H10K 2101/10; H10K 2101/20; H10K 2101/30; H10K 2101/70

(57) ABSTRACT

A light-emitting element includes a pair of electrodes, and a light-emitting layer between the pair of electrodes, wherein the light-emitting layer includes a first host material, a second host material, and a first light-emitting material exhibiting thermally activated delayed fluorescence, a concentration of the first host material is greater than a concentration of the second host material in the light-emitting layer, a band gap of the first host material is larger than a band gap of the second host material, a singlet excitation energy level of the first light-emitting material is lower than a singlet excitation energy level of the first host material, and a triplet excitation energy level of the second host material is lower than a triplet excitation energy level of the first host material.

### CROSS REFERENCE TO RELATED APPLICATIONS

This application claims the benefit of priority to Japanese Patent Application No. 2023-192081 filed on Nov. 10, 2023, the entire contents of which are incorporated herein by reference.

### FIELD

An embodiment of the present invention relates to a light-emitting element and a display device having the light-emitting element.

### BACKGROUND

In recent years, display devices having organic electroluminescence elements (OLEDs) have been widely used. In addition, organic electroluminescence elements exhibiting thermally activated delayed fluorescence or hyper-fluorescence (registered trademark) have attracted much attention because of their extremely high emission efficiency, and tremendous research and development are being conducted (see, for example, Japanese Patent Application Publications No. 2021-048366, 2020-013695, and 2017-222820).

### SUMMARY

An embodiment of the present invention is a light-emitting element. The light-emitting element includes a pair of electrodes, and a light-emitting layer between the pair of electrodes, wherein the light-emitting layer includes a first host material, a second host material, and a first light-emitting material exhibiting thermally activated delayed fluorescence, a concentration of the first host material is greater than a concentration of the second host material in the light-emitting layer, a band gap of the first host material is larger than a band gap of the second host material, a singlet excitation energy level of the first light-emitting material is lower than a singlet excitation energy level of the first host material, and a triplet excitation energy level of the second host material is lower than a triplet excitation energy level of the first host material.

An embodiment of the present invention is a display device. The display device includes a first pixel having a first light-emitting element, and a second pixel having a second light-emitting element, wherein the first light-emitting element has a pair of electrodes, and a first light-emitting layer between the pair of electrodes, the first light-emitting layer includes a first host material, a second host material, and a first light-emitting material exhibiting thermally activated delayed fluorescence, the second light-emitting element has the pair of electrodes, and a second light-emitting layer between the pair of electrodes, and the second light-emitting layer includes the second host material, and a second light-emitting material having a singlet excitation energy level higher than a singlet excitation energy level of the first light-emitting material, a concentration of the first host material is greater than a concentration of the second host material in the first light-emitting layer, a band gap of the first host material is larger than a band gap of the second host material, and a triplet excitation energy level of the second host material is lower than a triplet excitation energy level of the first host material.

### BRIEF DESCRIPTION OF DRAWINGS

FIG. 1 is a schematic cross-sectional view of a light-emitting element according to an embodiment of the present invention.

FIG. 2 is a schematic diagram representing the correlation of energy bands of a light-emitting element according to an embodiment of the present invention.

FIG. 3 is a schematic diagram representing the correlation of energy levels of a light-emitting element according to an embodiment of the present invention.

FIG. 4 is a schematic diagram representing the correlation of energy levels of a light-emitting element according to an embodiment of the present invention.

FIG. 5 is a schematic diagram representing the correlation of energy bands of a light-emitting element according to an embodiment of the present invention.

FIG. 6 is a schematic top view of a display device according to an embodiment of the present invention.

FIG. 7 is a schematic top view of a display device according to an embodiment of the invention.

FIG. 8 is a schematic top view of a display device according to an embodiment of the invention.

FIG. 9 is a schematic end view of a light-emitting element installed in a pixel of a display device according to an embodiment of the present invention.

FIG. 10 is a schematic end view of a display device according to an embodiment of the invention.

FIG. 11 is a voltage-current density curve of the light-emitting element manufactured in the example.

FIG. 12 is a constant current drive test result of the light-emitting element manufactured in the example.

FIG. 13 shows the voltage-current density curve of the light-emitting element manufactured in the example.

FIG. 14 shows the results of the constant current drive test of the light-emitting element manufactured in the example.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, the drawings are only an example, and do not limit the interpretation of the invention. In the specification and the drawings, the same reference number is provided to an element that is the same as that which appears in preceding drawings, and a detailed explanation may be omitted.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, the mode expressed by this expression includes a mode where the structure is not in contact with the other structure.

### First Embodiment

In the present embodiment, a light-emitting element 100 according to an embodiment of the present invention is explained.

### (Overall Configuration)

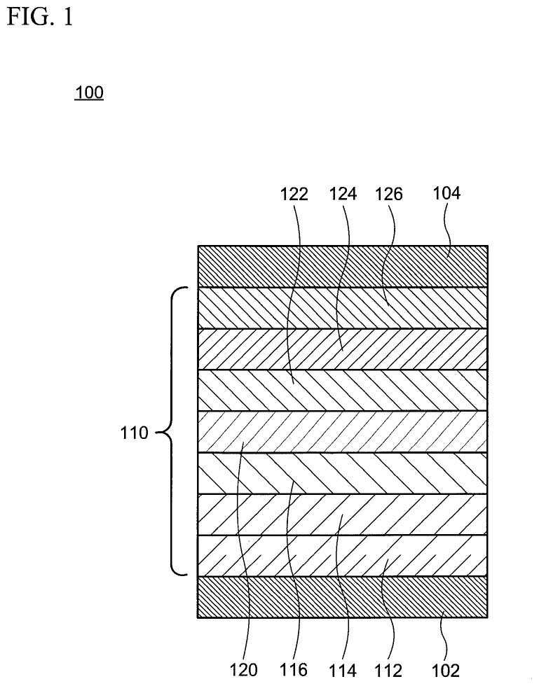

A schematic end view of the light-emitting element 100 is shown in FIG. 1. As shown in FIG. 1, the light-emitting element 100 has a pair of electrodes (anode 102 and cathode 104) and an electroluminescence layer (hereinafter also referred to as EL layer) 110 between the anode 102 and cathode 104. The EL layer 110 has at least a light-emitting layer 120.

As shown in FIG. 1, the EL layer 110 is composed of a light-emitting layer 120 as well as multiple functional layers including organic compounds. The EL layer 110 can have a hole-injection layer 112, a hole transporting layer 114, an electron blocking layer 116, a hole blocking layer 122, an electron transporting layer 124, and an electron-injection layer 126 and the like. When a potential difference is created between the anode 102 and cathode 104, holes and electrons are injected into the EL layer 110 from the anode 102 and cathode 104, respectively, and these carriers recombine in the light-emitting layer 120. The light-emitting material in the light-emitting layer 120 is excited by the recombination of the holes and the electrons, and the energy released when this excited state returns to the ground state can be extracted as light. Hereinafter, each component is explained.

### (A Pair of Electrodes)

The pair of electrodes can be the anode 102 and cathode 104. The anode 102 is an electrode for injecting holes into the EL layer 110. Since the anode 102 is configured to transmit visible light in the case where the light obtained in the EL layer 110 is extracted through the anode 102, the anode 102 is structured with a conductive oxide transmitting visible light such as indium-tin oxide (ITO) and indium-zinc oxide (IZO). On the other hand, when the light is extracted through the cathode 104, the anode 102 is configured to function as a reflective electrode efficiently reflecting the light. In this case, the anode 102 is configured to include a metal with high reflectivity such as silver and aluminum or an alloy thereof. For example, a structure in which a film containing a metal is sandwiched between films containing a conductive oxide may be applied to the anode 102.

The cathode 104 is an electrode for injecting electrons into the EL layer 110. Since the cathode 104 also functions as a reflecting electrode in the case where the light obtained in the EL layer 110 is extracted through the anode 102, the cathode 104 is configured to include the aforementioned metal or alloy (e.g., an alloy of silver and a metal having a small work function such as magnesium). On the other hand, when the light obtained in the EL layer 110 is extracted through the cathode 104, the cathode 104 is configured to include a conductive oxide transmitting visible light. Alternatively, a metal-containing film having a thickness (e.g., equal to or greater than 5 nm and equal to or less than 20 nm) allowing visible light to pass therethrough may be used as the cathode 104. In the latter case, a film of a conductive oxide transmitting visible light may be provided over the metal-containing film.

### (Hole-Injection Layer)

The hole-injection layer 112 functions to promote hole injection from the anode 102 to the EL layer 110. A compound to which holes are easily injected, i.e., a (electron-donating) compound which is readily oxidized can be used in the hole-injection layer 112. In other words, a compound with a shallow highest occupied molecular orbital (HOMO) level can be used. For example, an aromatic amine such as a benzidine derivative and a triarylamine, a carbazole derivative, a thiophene derivative, a phthalocyanine derivative such as copper phthalocyanine, and the like can be used. Alternatively, a polymeric material such as polythiophene, polyaniline, and their derivatives can be used, and poly(ethylenedioxythiophene)/poly(styrenesulfonic acid) is represented as an example. A mixture of an electron-donating compound such as the aforementioned aromatic amine and carbazole derivative and an aromatic hydrocarbon with an electron acceptor may be used. The electron acceptor includes a transition metal oxide such as vanadium oxide and molybdenum oxide, a nitrogen-containing heteroaromatic compound, and an aromatic compound with a strong electron-withdrawing group such as a cyano group. The mixture ratio of the mixture of electron-donating compound and electron acceptor should be 20 to 50 vol % electron-donating compound and 1 to 1.5 vol % electron acceptor in the hole-injection layer 112. The hole-injection layer 112 may have a single layer structure or may be composed of a plurality of layers containing different materials.

### (Hole-Transporting Layer)

The hole transporting layer 114 is provided in contact with the hole-injection layer 112. The hole transporting layer 114 has a function of transporting the holes injected into the hole-injection layer 112 to the light-emitting layer 120, and a material the same as or similar to the material usable in the hole-injection layer 112 can be used. For example, a material with a deeper HOMO level than the hole-injection layer 112, but with a difference therebetween of 0.5 eV or less can be used. Typically, an aromatic amine such as a benzidine derivative may be used. The hole transporting layer 114 may also have a single layer structure or may be composed of a plurality of layers containing different materials.

### (Electron-Blocking Layer)

The electron-blocking layer 116 is provided in contact with the hole transporting layer 114. The electron-blocking layer 116 has a function to confine electrons in the light-emitting layer 120 by preventing the electrons injected from the cathode 104 from passing through the light-emitting layer 120 and being injected into the hole transporting layer 114 without contributing to recombination in the light-emitting layer 120 as well as a function to prevent energy transfer from the excitation energy obtained in the light-emitting layer 120 to the molecules in the hole transporting layer 114. These functions prevent a decrease in emission efficiency.

It is preferable to use a material in the electron-blocking layer 116 which has higher or comparable hole transport properties than electron transport properties and which has a shallower lowest unoccupied molecular orbital (LUMO) level and a larger band gap than the molecules in the light-emitting layer 120. Specifically, the difference between the LUMO level of the molecules in the electron-blocking layer 116 and that of the molecules in the light-emitting layer 120 is preferred to be 0.2 eV or greater, 0.3 eV or greater, or 0.5 eV or greater. In addition, the difference between the band gap of the molecules in the electron-blocking layer 116 and that of the molecules in the light-emitting layer 120 is preferred to be 0.2 eV or greater, 0.3 eV or greater, or 0.5 eV or greater. Specifically, an aromatic amine derivative, a carbazole derivative, a 9,10-dihydroacridine derivative, a benzofuran derivative, a benzothiophene derivative, and the like may be used in the electron-blocking layer 116. The electron-blocking layer 116 may also have a single layer structure or may be composed of a plurality of layers containing different materials.

### (Light-Emitting Layer)

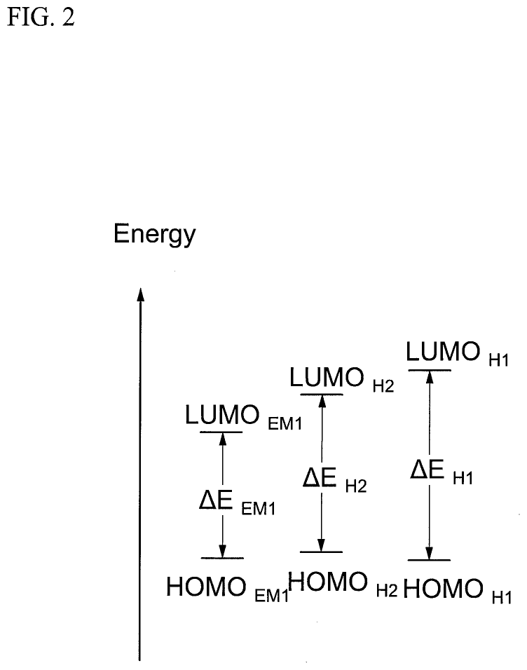

The light-emitting layer 120 includes the first host material as the main component, the second host material, and the first light-emitting material responsible for light emission. Referring to FIG. 2, the correlation of the energy bands of the first host material, the second host material, and the first light-emitting material is described.

FIG. 2 is a schematic diagram showing the correlation of the energy bands of the first host material, the second host material, and the first light-emitting material in the light-emitting layer 120. The LUMO level (LUMO_{H1}) of the first host material should be higher than the LUMO level (LUMO_{H2}) of the second host material, and the HOMO level (HOMO_{H1}) of the first host material should be lower or equal to the HOMO level (HOMO_{H2}) of the second host material. The band gap (ΔE_{H1}), which is the energy difference between the LUMO and HOMO levels of the first host material, is greater than the band gap (ΔE_{H2}), which is the energy difference between the LUMO and HOMO levels of the second host material. The LUMO level of the first host material is, for example, −2.4 eV to −2.6 eV, and the HOMO level of the first host material is −5.9 eV to −6.1 eV. The LUMO level of the second host material is, for example, −2.8 eV to −3.0 eV, and the HOMO level of the second host material is −5.8 eV to −6.0 eV. With such an energy band correlation between the first and second host materials, carriers injected from a pair of electrodes are injected into the first host material and then promptly injected into the second host material.

The LUMO level of the first host material is higher than the LUMO level (LUMO_{EM1}) of the first light-emitting material. The difference between the LUMO level of the first host material and the LUMO level of the first light-emitting material is, for example, 0.7 eV or more and 1.1 eV or less. The LUMO level of the first host material is higher than the LUMO level of the first light-emitting material, and the difference is large.

The HOMO level of the first host material should be lower or equal to the HOMO level of the first light-emitting material. The band gap ΔE_{H1} of the first host material is greater than the band gap ΔE_{EM1} of the first light-emitting material. With such an energy level correlation between the first host material and the first light-emitting material, the LUMO level of the first host material is higher than the LUMO level of the first light-emitting material.

The LUMO level of the second host material is preferably higher than the LUMO level of the first light-emitting material, and the HOMO level of the second host material is preferably higher than the HOMO level of the first light-emitting material. The band gap ΔE_{H2} of the second host material should be larger than the band gap ΔE_{EM1} of the first light-emitting material. For example, if the light-emitting material in the light-emitting layer exhibits green emission, the second host material has a band gap larger than the band gap of the light-emitting material exhibiting blue emission. Blue emission is an emission having an emission peak wavelength is in the range of 400 nm or longer and 500 nm or shorter. The band gap of the second host material should be about 3 eV, for example. By having such a correlation between the energy levels of the second host material and the first light-emitting material, the emission energy of the first light-emitting material is suppressed from being absorbed or transferred to the second host material, and the emission energy of the first light-emitting material can be obtained as the emission of the light-emitting element 100.

The LUMO level of the first light-emitting material should be lower than the LUMO level of the first and second host materials and higher than or equal to the HOMO level of the first host material. The band gap ΔE_{EM1} of the first light-emitting material is smaller than the band gap ΔE_{H1} of the first host material and the band gap ΔE_{H2} of the second host material. The LUMO level of the first light-emitting material is, for example, −3.3 to −3.5 eV, and the HOMO level of the first light-emitting material is, for example, −5.8 to −6.1 eV. Such an energy level correlation and small band gap of the first light-emitting material allows the light-emitting element 100 to exhibit an emission color of the first light-emitting material.

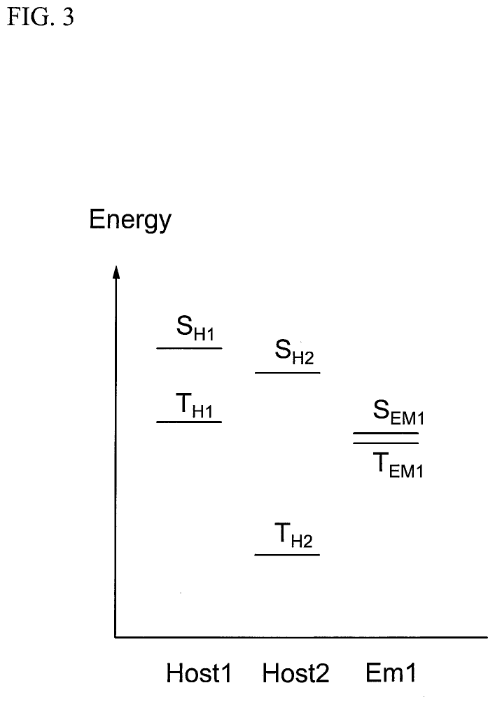

Referring now to FIG. 3, the energy levels of the first host material, the second host material, and the first light-emitting material in the light-emitting layer 120 are explained.

FIG. 3 is a schematic diagram showing the correlation of the energy levels of the first host material, the second host material, and the first light-emitting material. In the light-emitting layer 120, the singlet excitation energy (S1) level (S_{H1}) of the first host material (Host1) is higher than the S1 level S_{EM1} of the first light-emitting material, and the triplet excitation energy (T1) level (T_{H1}) of the first host material is higher than the T1 level (T_{EM1}) of the first light-emitting material. With such an energy level correlation between the first host material and the first light-emitting material, the singlet and triplet excitation energies of the singlet and triplet excited states of the first host material formed by carrier recombination in the first host material are respectively S1 and T1 levels, respectively.

The first light-emitting material is a material that exhibits thermally active delayed fluorescence. The difference between the T1 and S1 levels of the first light-emitting material is small, for example, 5 meV or more and 20 meV or less. Therefore, the triplet excited state of the first light-emitting material produced by energy transfer can reverse intersystem crossing to a singlet excited state by very small thermal energy at room temperature or lower. Furthermore, as described below, since the concentration of the first light-emitting material in the light-emitting layer 120 is relatively high, a singlet excited exciton can be formed by TTA (Triplet-triplet annihilation) of the first light-emitting material. As a result, radiation deactivation from the singlet excited state generated by TTA can be used for emission, and high emission efficiency can be achieved. However, when using TTA, only a single molecule of a singlet exciton can be generated from two triplet excitons. On the other hand, the first light-emitting material can undergo reverse intersystem crossing from the triplet excited state to the singlet excited state by a small thermal energy, as described above. Therefore, the contribution of TTA can be reduced by using this reverse intersystem crossing so that singlet excitons can be efficiently formed from triplet excitons in the first light-emitting material. As a result, the light-emitting element 100 can exhibit high emission efficiency.

The S1 level (S_{H2}) of the second host material (Host2) is higher than the S1 level of the first light-emitting material (Em1) and lower than the S1 level of the first host material. The T1 level (T_{H2}) of the second host material is lower than the T1 level of the first light-emitting material and the T1 level of the first host material. This energy level correlation between the second host material, the first light-emitting material and the first host material allows the singlet and triplet excitation energies of the first host material to transfer efficiently to the S1 and T1 levels of the first light-emitting material. Conventionally, the formation of singlet excitons of the first light-emitting material has been encouraged by increasing the concentration of the first light-emitting material. However, the second host material can better promote the formation of singlet excited states of the first light-emitting material by being correlated with the energy levels described above.

In the light-emitting layer 120, the concentration of the second host material is smaller than the concentration of the first host material. In other words, the concentration of the first host material is greater than the concentration of the second host material in the light-emitting layer 120. In the light-emitting layer 120, the concentration of the first host material should be 20 vol % or greater and 80 vol % or less, and the concentration of the second host material should be 5 vol % or greater and 10 vol % or less. The energy levels of the second host material are correlated as described above, and the small concentration of the second host material allows the singlet and triplet excitation energies of the first host material to be transferred more efficiently to the S1 and T1 levels of the first light-emitting material.

Further, the concentration of the second host material is preferably smaller than the concentration of the first light-emitting material in the light-emitting layer 120. The concentration of the first light-emitting material may be greater than the concentration of the first host material in the light-emitting layer 120. The concentration of the first light-emitting material should be 20 vol % or greater and 60 vol % or less in the light-emitting layer 120. The concentration of the second host material being smaller than the concentration of the first light-emitting material in the light-emitting layer 120 can promote TTA of the first light-emitting material.

A variety of compounds can be used as the first host material, depending on the emission wavelength of the light-emitting material. For example, as the host material, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, an aromatic amine derivative, and a carbazole derivative can be used in addition to zinc and aluminum-based metal complexes.

For the second host material, a material having a band gap smaller than that of the first host material is used, as described above. For the second host material, it is preferable to use a material having an electron mobility of 1×10⁻¹¹ cm²/Vs or higher and 1×10⁻⁶ cm²/Vs or lower. For example, carbazole derivatives, stilbene derivatives, distilbenzene derivatives, anthracene derivatives, rubrene derivatives, etc. can be used as the second host material.

As described above, a material that exhibits thermally activated delayed fluorescence (TADF) (thermally activated delayed fluorescent material) is used for the first light-emitting material. For the first light-emitting material, it is preferable to use a material that exhibits an emission color between green and yellow. Here, green emission is the emission having an emission maximum peak wavelength located in the range of 500 nm or longer and 570 nm or shorter, and yellow emission is the emission having an emission maximum peak wavelength located in the range of 570 nm or longer and 650 nm or shorter.

Examples of the thermally activated delayed fluorescence materials include a fullerene and its derivatives, and an acridine derivative such as proflavine, eosin, and the like. A metal-containing porphyrin containing magnesium, zinc, cadmium, tin, platinum, indium, or palladium is also represented. A metal-containing porphyrin includes, for example, a protoporphyrin-tin fluoride complex, a mesoporphyrin-tin fluoride complex, a hematoporphyrin-tin fluoride complex, a coproporphyrin tetramethyl ester-tin fluoride complex, an octaethylporphyrin-tin fluoride complex, an ethioporphyrin-tin fluoride complex, an octaethylporphyrin-platinum chloride complex, and the like.

In addition, a compound in which an electron-donor component and an electron-acceptor component are linked may be used. As the electron-donor component and the electron-acceptor component, a π-electron-excessive heteroaromatic ring and a π-electron-deficient heteroaromatic ring are respectively represented. The basic skeleton of the π-electron-excessive heteroaromatic ring includes a pyridine skeleton, a diazine skeleton, a triazine skeleton, and the like. The basic skeleton of the π-electron-deficient heteroaromatic ring includes an acridine skeleton, a phenoxazine skeleton, a phenothiazine skeleton, a furan skeleton, a thiophene skeleton, a pyrrole skeleton, and the like. As such compounds, 2-(biphenyl-4-yl)-4,6-bis(12-phenylindolo[2,3-a]carbazole-11-yl)-1,3,5-triazine, 9-(4,6-diphenyl-1,3,5-triazine-2-yl)-9′-phenyl-9H,9′H-3,3′-bicarbazole, 9-[4-(4,6-diphenyl-1,3,5-triazine-2-yl)phenyl]-9′-phenyl-9H,9′H-3,3-biucarbazole, 2-[4-(10H-phenoxazin-10-yl)phenyl]-4,6-diphenyl-1,3,5-triazine, and the like are exemplified.

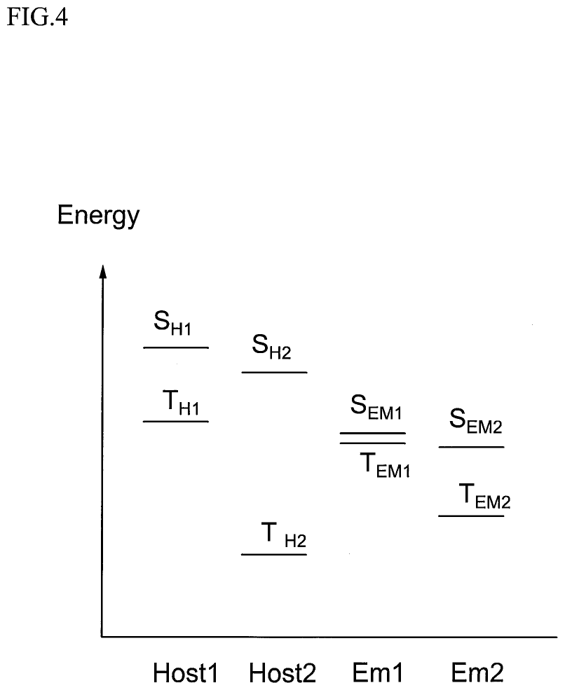

In addition to the first light-emitting material, which is a thermally activated delayed fluorescent material, the light-emitting layer 120 may also include a fluorescent material capable of receiving the excited singlet energy of the first light-emitting material to form a singlet excited state (hereinafter referred to as a second light-emitting material). Referring to FIG. 4, the energy correlation between the second light-emitting material and other materials in the light-emitting layer 120 is explained.

FIG. 4 is a schematic diagram representing the energy levels of the first host material, the second host material, the first light-emitting material, and the second light-emitting material in the light-emitting layer. The second light-emitting material (Em2) should have a lower S1 level (S_{EM2}) than the S1 level of the first light-emitting material, as shown in FIG. 4. The second light-emitting material should have a T1 level (T_{EM2}) lower than the T1 level of the first light-emitting material. The second light-emitting material preferably has a T1 level higher than the T1 level of the second host material. The second light-emitting material should have a band gap that is smaller than or equal to the band gap of the first light-emitting material. Such a correlation between the energy levels of the second light-emitting material and the first light-emitting material allows singlet excitation energy of the first light-emitting material to be transferred to the S1 level of the second light-emitting material, and the light-emitting element 100 can exhibit emission of the emission color of the second light-emitting material.

The second light-emitting material is preferably included in the light-emitting layer 120 in a concentration smaller than the concentration of the first light-emitting material. For example, the concentration of the second light-emitting material is 0.1 vol % or greater and 1.0 vol % or less in the light-emitting layer 120.

A fluorescent material is preferred for the second light-emitting material. For the second light-emitting material, it is preferred to use a material that emits colors between green and yellow and red. Specifically, a fluorescent material such as a coumarin derivative, a pyran derivative, a quinacridone derivative, a tetracene derivative, a pyrene derivative, an anthracene derivative, and a pyran derivative are exemplified. In general, the emission spectrum exhibited by thermally activated delayed fluorescent materials is broad and has low color purity. In contrast, since the fluorescent materials described above provide an emission spectrum with a relatively narrow half width, they are capable of emitting light with high color purity. Therefore, further addition of the second light-emitting material to the light-emitting layer 120 enables the production of the light-emitting element 100 with excellent color purity in addition to high emission efficiency resulting from the thermally activated delayed fluorescence material.

### (Hole-Blocking Layer)

The hole-blocking layer 122 has a function to confine the holes injected from the anode 102 within the light-emitting layer 120 by preventing the holes from passing through the light-emitting layer 120 and being injected into the electron-transporting layer 124 without contributing to recombination as well as a function to prevent the excitation energy obtained in the light-emitting layer 120 from being transferred to the molecules in the electron-transporting layer 124. This mechanism prevents a decrease in emission efficiency.

For the hole-blocking layer 122, it is preferable to use a material having higher or comparable electron-transporting properties than hole-transporting properties as well as a deeper HOMO level and larger band gap than the molecules in the light-emitting layer 120. Specifically, the difference between the HOMO level of the molecules in the hole-blocking layer 122 and that of the molecules in the light-emitting layer 120 is preferred to be 0.2 eV or greater, 0.3 eV or greater, or 0.5 eV or greater. The difference between the band gap of the molecules in the hole-blocking layer 122 and that of the molecules in the light-emitting layer 120 is also preferred to be 0.2 eV or greater, 0.3 eV or greater, or 0.5 eV or greater. Specifically, a phenanthroline derivative, an oxadiazole derivative, a triazole derivative, a metal complex having a relatively large band gap (e.g., 2.8 eV or higher) such as bis(2-methyl-8-quinolinolato)(4-hydroxy-biphenylyl)aluminum, and the like are represented. The hole-blocking layer 122 may also have a single layer structure or may be composed of a plurality of layers containing different materials.

### (Electron-Transporting Layer)

The electron-transporting layer 124 functions to transport the electrons injected from the cathode 104 via the electron-injection layer 126 to the light-emitting layer 120. A readily reduced (electron-accepting) compound can be used for the electron-transporting layer 124. In other words, a compound with a shallow LUMO level may be used. For example, a metal complex containing a ligand having benzoquinolinol as the basic skeleton such as tris(8-quinolinolato)aluminum and tris(4-methyl-8-quinolinolato)aluminum, and a metal complex containing a ligand having oxadiazole or thiazole as the basic skeleton, and the like are represented. In addition to these metal complexes, a compound with an electron-deficient heteroaromatic ring such as an oxadiazole derivative, a thiazole derivative, a triazole derivative, and a phenanthroline derivative may be used. The electron-transporting layer 124 may also have a single layer structure or may be composed of a plurality of layers containing different materials.

For the electron-injection layer 126, a compound promoting electron injection from the cathode 104 to the electron-transporting layer 124 can be used. For example, a mixture of a compound which can be used for the electron-transporting layer 124 and an electron donor such as lithium and magnesium may be used. Alternatively, an inorganic compound such as lithium fluoride and calcium fluoride may be used.

The anode 102 is formed using chemical vapor deposition (CVD), vapor deposition, or sputtering methods, etc. Each layer in the EL layer 110 is formed by inkjet, spin coating, printing, or vapor deposition. In the light-emitting layer 120, three or even four materials including a first host material, a second host material, and a first light-emitting material, or even a second light-emitting material, may be deposited simultaneously. In this case, the quaternary co-evaporation method or the ternary co-evaporation method using a mixture (premix) of the first and second host materials may be used to form the light-emitting layer 120. The cathode 104 is formed by chemical vapor deposition (CVD), vapor deposition, sputtering, or co-evaporation.

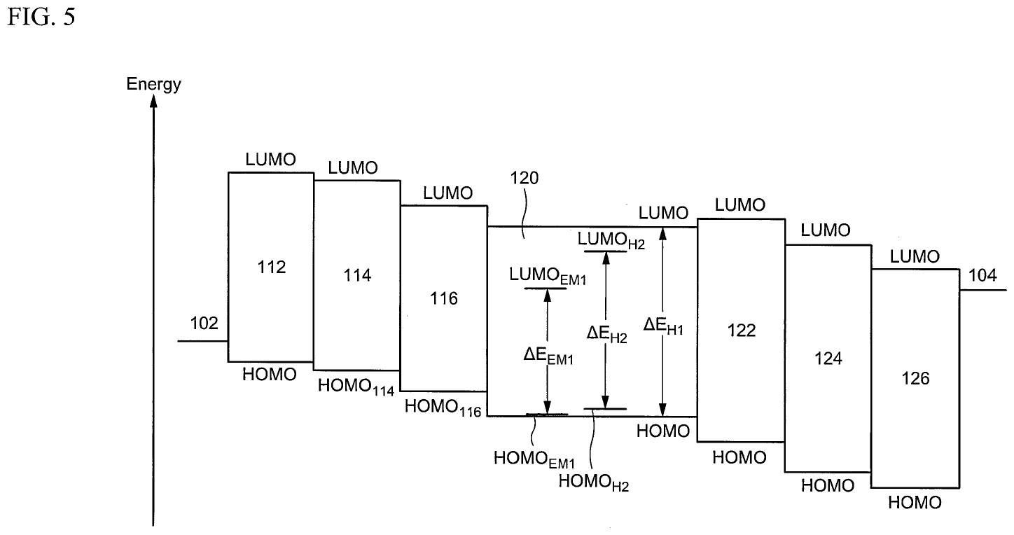

FIG. 5 shows a schematic diagram of the energy band correlations of a light-emitting element in an embodiment of the present invention. FIG. 5 shows the HOMO and LUMO levels of the functional and light-emitting layers in the EL layer 110. In FIG. 5, 102 shows the Fermi level of the anode 102, and 104 shows the Fermi level of the cathode 104.

As shown in FIG. 5, the LUMO levels of the hole-injection layer 112, hole transporting layer 114, electron blocking layer 116, and light-emitting layer 120 are lower in that order. The LUMO level of the light-emitting layer 120 is lower than that of the hole blocking layer 122. The LUMO level is lower in the order of the hole blocking layer 122, electron transporting layer 124, and electron-injection layer 126. At the HOMO level, the following layers are lower in order: hole-injection layer 112, hole transporting layer 114, electron blocking layer 116, light-emitting layer 120, hole blocking layer 122, electron transporting layer 124, and electron-injection layer 126.

As described above, in the light-emitting element 100, the light-emitting layer has a first host material, a second host material, and a first light-emitting material that exhibits thermally activated delayed fluorescence. The band gap of the first host material is larger than that of the second host material, and the triplet excitation energy level of the second host material is lower than the triplet excitation energy level of the first host material, which enables high emission efficiency to be obtained without increasing the concentration of the first light-emitting material, and the emission lifetime is significantly improved. Therefore, a highly reliable display device can be provided.

### Second Embodiment

The present embodiment describes a display device 200 equipped with the light-emitting element 100 described in the first embodiment. Descriptions may be omitted for configurations identical or similar to those described in the first embodiment. In the present embodiment, a display device 200 including the light-emitting element 100 described in the First Embodiment is explained. An explanation of the structure the same as or similar to that described in the First Embodiment may be omitted.

### (Overall Structure)

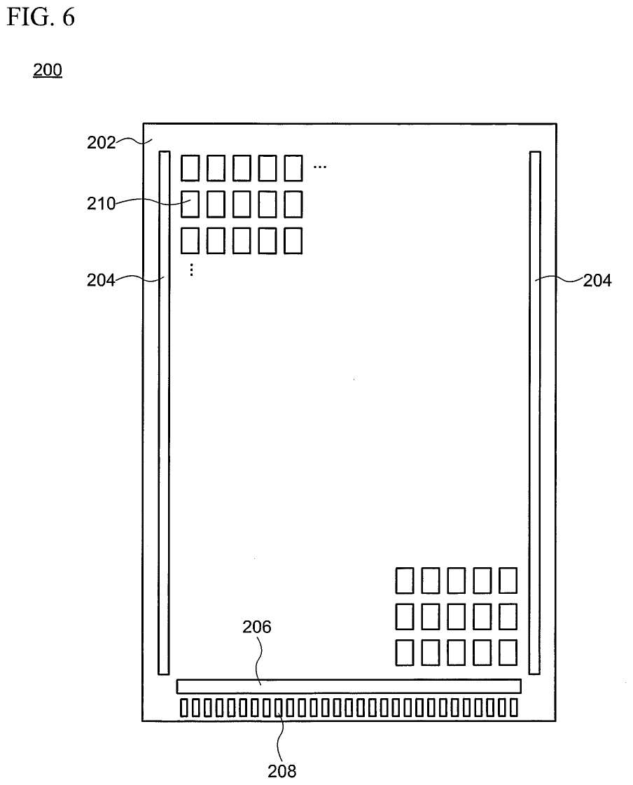

A schematic top view of the display device 200 is shown in FIG. 6. As shown in FIG. 6, the display device 200 has a substrate 202 over which a variety of patterned insulating films, semiconductor films, and conductor films is stacked. Appropriate stacking of these films leads to the formation of a plurality of pixels 210, and driver circuits for driving the pixels 210 (scanning-line driver circuits 204 and a signal-line driver circuit 206), and the like over the substrate 202. A counter substrate which is not illustrated in FIG. 6 is provided over the pixels 210, the scanning-line driver circuits 204, and the signal-line driver circuit 206. The substrate 202 and the counter substrate are secured by an adhesive such as a sealant, by which the pixels 210, the scanning-line driver circuits 204, and the signal-line driver circuit 206 are sealed and protected. A plurality of terminals 208 formed with a conductive film is provided over the substrate 202, and the terminals 208 are electrically connected to an external circuit which is not illustrated via a connector such as a flexible printed circuit (FPC) board. A variety of signals and power for displaying images are supplied from the external circuit to the scanning-line driver circuits 204 and the signal-line driver circuit 206 through the terminals 208. Note that either or both of the scanning-line driver circuits 204 and the signal-line driver circuit 206 need not be formed directly over the substrate 202, and a driver circuit formed over a substrate different from the substrate 202 (such as a semiconductor substrate) may be mounted over the substrate 202 or the connector.

In each of the pixels 210, a pixel circuit is formed, and one of the light-emitting elements giving the three primary colors (i.e., a red-emissive light-emitting element, a green-emissive light-emitting element, and a blue-emissive light-emitting element) is further arranged. Signals to drive the pixel circuits are generated by the scanning-line driver circuits 204 and the signal-line driver circuit 206 on the basis of various signals supplied from the external circuits, by which the light-emitting elements connected to the pixel circuits emit light to allow each of the pixels 210 to function as the smallest unit providing color information. As a result, full-color display can be performed. Here, a red-emissive light-emitting element, a green-emissive light-emitting element, and a blue-emissive light-emitting element are, for example, elements respectively exhibiting emission peak wavelengths in the range of 650 nm or longer and 750 nm or shorter, 500 nm or longer and 570 nm or shorter, and 400 nm or longer and 500 nm or shorter.

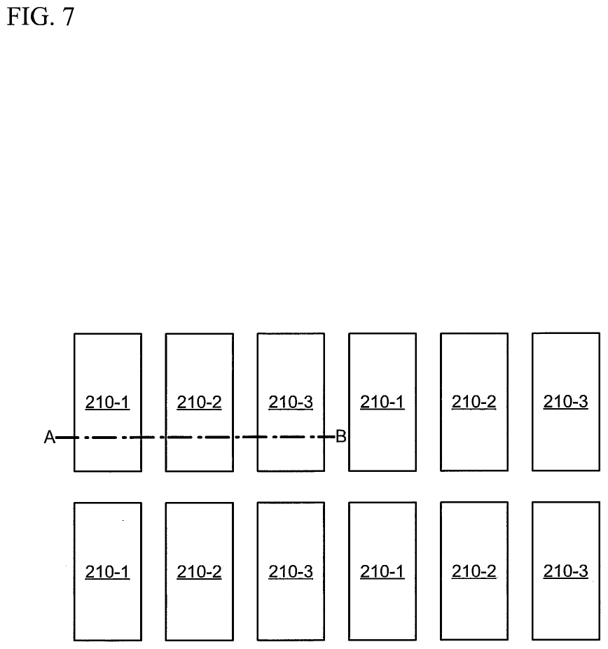

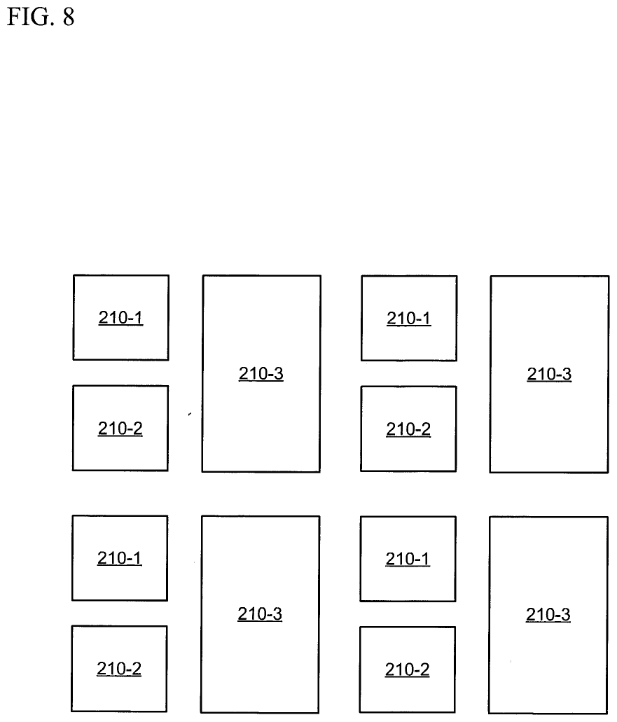

There is no restriction on the arrangement of the pixels 210. For example, the stripe arrangement may be employed in which the red-, green-, and blue-emissive pixels 210-1, 210-2, and 210-3 respectively providing red, green, and blue light are arranged sequentially in the line direction, and the pixels 210 providing the same emission color are arranged in the same row as shown in FIG. 7. Alternatively, although not illustrated, in addition to the mosaic arrangement in which the red-emissive pixel 210-1, the green-emissive pixel 210-2, and the blue-emissive pixel 210-3 are sequentially arranged in both the row and column directions, a variety of arrangements such as the delta arrangement and the pentile arrangement may be employed. Alternatively, the plurality of pixels 210 may be arranged so that one or more red-emissive pixels 210-1 and one or more green-emissive pixels 210-2 are sandwiched between adjacent blue-emissive pixels 210-3 as shown in FIG. 8. In this arrangement, the plurality of pixels 210 may be arranged so that the blue-emissive pixel 210-3 in which the blue-emissive light-emitting element with the lowest emission efficiency is arranged has a larger area than the other pixels 210, by which the burden on the blue-emissive light-emitting element is reduced and the reliability of the display device 200 can be improved.

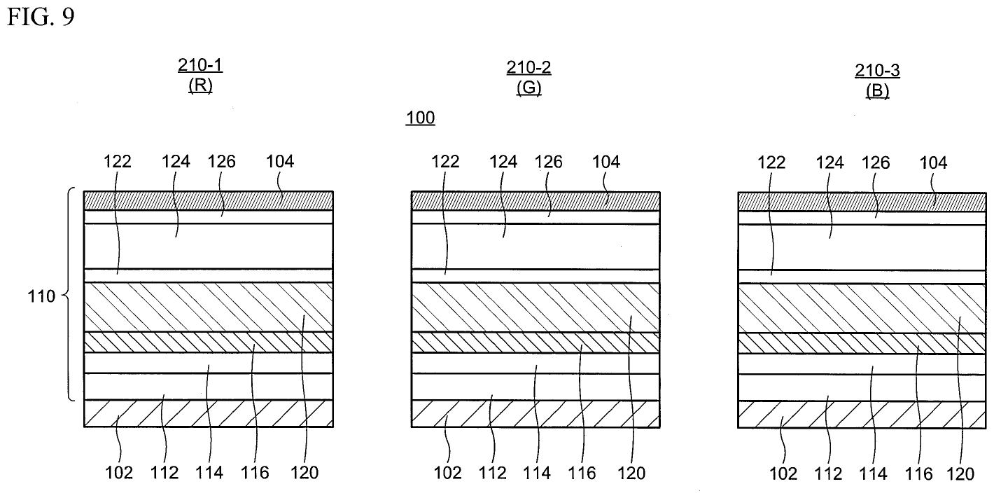

At least one of the red-emissive pixel 210-1, the green-emissive pixel 210-2, and the blue-emissive pixel 210-3 is arranged with the light-emitting element 100 described in the First Embodiment. For example, as shown in FIG. 9, a light-emitting element with a different structure than the light-emitting element 100 can be placed in the red-emissive pixel 210-1 and the blue-emissive pixel 210-3, and the light-emitting element 100 can be placed in the green-emissive pixel 210-2. In this case, the second host material used for the light-emitting layer 120 of the green-emissive pixel 210-2 can be used as the host material for the light-emitting layer 120 of the blue-emissive pixel 210-3. Furthermore, the light-emitting material of the light-emitting layer 120 of the blue-emissive pixel 210-3 can be a light-emitting material having a singlet excitation energy level higher than the singlet excitation energy level of the first light-emitting material of the light-emitting layer 120 of the green-emissive pixel 210-2. In other words, the emission color of the light-emitting material of the light-emitting layer 120 of the blue-emissive pixel can be blue. For the red-emissive pixel 210-1 and the blue-emissive pixel 210-3, a light-emitting element including a fluorescent material (which does not show activation delayed fluorescence) or a phosphorescent material in the light-emitting layer 120 can be arranged.

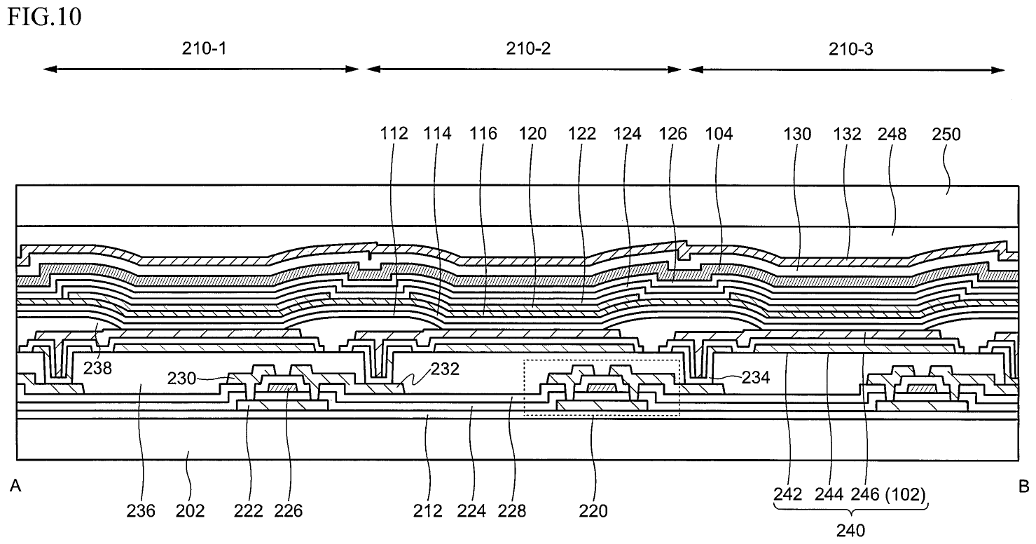

A schematic view of a cross section along the chain line A-B in FIG. 7 is shown in FIG. 10. In FIG. 10, the cross section including the continuously arranged red-emissive pixel 210-1, green-emissive pixel 210-2, and blue-emissive pixel 210-3 is schematically illustrated. The configuration of the pixel circuit formed in each of the pixels 210 may be arbitrarily determined, and any known configuration may be applied. In the example shown in FIG. 10, one transistor 220 and a capacitor element (auxiliary capacitor element) 240 connected to the transistor 220 are shown as part of the elements structuring the pixel circuit. Furthermore, a light-emitting element connected to the pixel circuit is provided in each pixel 210. In the example shown in FIG. 10, the combination shown in FIG. 9 is applied. That is, light-emitting elements with a different structure than the light-emitting element 100 are arranged in the red-emissive pixel 210-1 and the blue-emissive pixel 210-3, and the light-emitting element 100 is arranged in the green-emissive pixel 210-2. Although an example is demonstrated here in which the light from the emission layers 120 is extracted through the counter substrate 250 in all of the light-emitting elements, the display device 200 may be configured so that the light from the emission layers 120 is extracted through the substrate 202.

### (Substrate and Counter Substrate)

The substrate 202 and the counter substrate 250 are provided to give physical strength to the display device 200 and to protect the plurality of pixels 210, the scanning-line driver circuits 204, and the signal-line driver circuit 206. The substrate 202 and the counter substrate 250 may be an inorganic material-containing substrate such as a crystalline semiconductor substrate, a glass substrate, and a quartz substrate or may contain a polymer such as a polyimide, a polyamide, and a polycarbonate. The substrate 202 and the counter substrate 250 may or may not be flexible. In the former case, the substrate 202 and/or the counter substrate 250 may be sufficiently flexible to be elastically deformed or highly flexible enough to be plastically deformed. When the emission from the light-emitting elements is extracted through the counter substrate 250, at least the counter substrate 250 is configured to transmit visible light. Conversely, when the emission from the light-emitting elements is extracted through the substrate 202, at least the substrate 202 is configured to transmit visible light.

### (Pixel Circuit)

As described above, since a known configuration may be applied as the pixel circuit, a detailed description is omitted. In the example shown in FIG. 10, the transistor 220 functioning as a driving transistor is provided over the substrate 202. The transistor 220 may be provided directly over the substrate 202 or may be formed over the substrate 202 through an undercoat 212 which prevents the diffusion of impurities contained in the substrate 202. The transistor 220 shown in FIG. 10 is composed of a semiconductor film 222, a gate insulating film 224 over the semiconductor film 222, a gate electrode 226 over the gate insulating film 224, an interlayer insulating film 228 over the gate electrode 226, and a pair of terminals 230 and 232 disposed over the interlayer insulating film 228 and electrically connected to the semiconductor film 222. Although the transistor 220 shown here is a top-gate type transistor, there is no restriction on the structure of the transistor 220, and a bottom-gate type transistor or a transistor having gate electrodes over and under the semiconductor film may be used as the transistor 220.

A leveling film 236 is provided over the transistor 220 to absorb unevenness caused by the elements such as the transistor 220 included in the pixel circuit and to provide a flat surface. The capacitor electrode 242, a capacitor insulating film 244 over the capacitor electrode 242, and a pixel electrode 246 may be arranged over the leveling film 236, and the capacitor element 240 can be manufactured by these components. Here, the pixel electrode 246 functions as the anode 102 of the light-emitting element 100. An opening is provided in the leveling film 236 to expose the terminal 232, and the pixel electrode 246 is electrically connected to the terminal 232 at this opening either directly or via a connecting electrode 234 covering this opening. A partition wall 238, which is an insulating film, is provided to cover the edge of the pixel electrode 246, and the EL layer 110 is arranged to cover the pixel electrode 246 and the partition wall 238. This structure electrically insulates adjacent light-emitting elements 100 and prevents the EL layer 110 from being disconnected by the edge of the pixel electrode 246. Note that, in the example shown in FIG. 10, the pixel electrode 246 is shared by the light-emitting element 100 and the capacitor element 240.

### (Light-Emitting Element)

As described above, the light-emitting elements with a different structure than the light-emitting element 100 are arranged in the red-emissive pixel 210-1 and the blue-emissive pixel 210-3, and the light-emitting element 100 is arranged in the green-emissive pixel 210-2. Therefore, all or part of the functional layers other than the light-emitting layer 120 may be provided continuously over all of the pixels 210 so as to be shared by all of the pixels 210. For example, the electron-blocking layer 116 may be formed so as to be shared by all of the pixels 210 and to be continuous over all of the pixels 210 as shown in FIG. 10. As shown in FIG. 10, in addition to the electron-blocking layer 116, the hole-injection layer 112, the hole-transporting layer 114, the hole-blocking layer 122, the electron-transporting layer 124, the electron-injection layer 126, and the cathode 104 may also be provided so as to be shared by all of the pixels 210 and to be provided continuously over all of the pixels 210.

### (Other Component)

As an optional component, one or a plurality of cap layers 130 may be provided over the cathode 104 to resonate the light extracted from the cathode 104 to improve color purity and luminance in the frontal direction. In addition, a protective film 132 may be disposed over the light-emitting elements to prevent impurities such as water and oxygen from entering the EL layer 110. The protective film 132 may be composed of, for example, a film containing silicon nitride, a film containing a polymer such as an acrylic resin and an epoxy resin, or a stack thereof.

### EXAMPLES

### Example 1

The present example shows the manufacture of the light-emitting element 100 described in the first embodiment and the evaluation of its characteristics. Specifically, the light-emitting element 1 of the embodiment of the present invention and the comparative light-emitting element 1 as a comparative example were manufactured. The light-emitting element 1 is one of the light-emitting elements 100 of the first embodiment, and the comparative light-emitting element 1 is identical in all respects to light-emitting element 1 except for identical the configuration which does not include a second host material in the light-emitting layer 120. The configurations of the light-emitting element 1 and the comparative light-emitting element 1 are shown in Table 1. The composition of the light-emitting layer 120 of each light-emitting element is shown in Table 2.

TABLE 1
Thickness of EL layers of light-emitting elements and of Examples and Comparative examples

| | | Hole- | Hole- | Electron- | Light- | Hole- | Electron- | Electron- | |
|---|---|---|---|---|---|---|---|---|---|
| | | injection | transporting | blocking | emitting | blocking | transporting | injection | |
| | anode | layer | layer | layer | layer | layer | layer | layer | Cathode |
| Thickness | 50 | 17 | 40 | 5 | 45 | 10 | 20 | 2 | 160 |
| (nm) | | | | | | | | | |

TABLE 2
The composition of the Light-emitting layer of Light-
emitting elements of Example and Comparative example

| | Light-emitting layer | | |
|---|---|---|---|
| | First host | First light- | Second host |
| | material | emitting material | material |
| | (vol %) | (vol %) | (vol %) |
| Comparative light- | 50 | 50 | — |
| emitting element 1 | | | |
| Light-emitting element 1 | 45 | 50 | 5 |

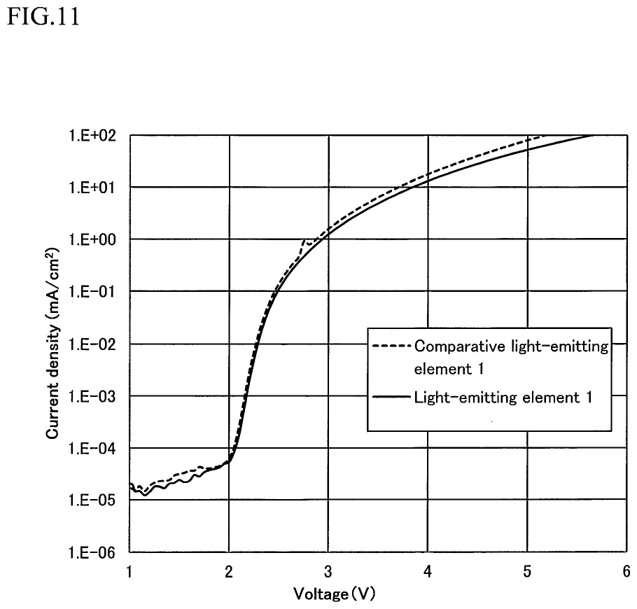

The current density-voltage properties of light-emitting element 1 and comparative light-emitting element 1 were measured. FIG. 11 shows the measurement results of the current density-voltage properties.

As shown in FIG. 11, light-emitting element 1 exhibited current density-voltage properties equivalent to those of comparative light-emitting element 1 and showed high current efficiency equivalent to that of comparative light-emitting element 1. Light-emitting element 1 and comparative light-emitting element 1 exhibited green light emission.

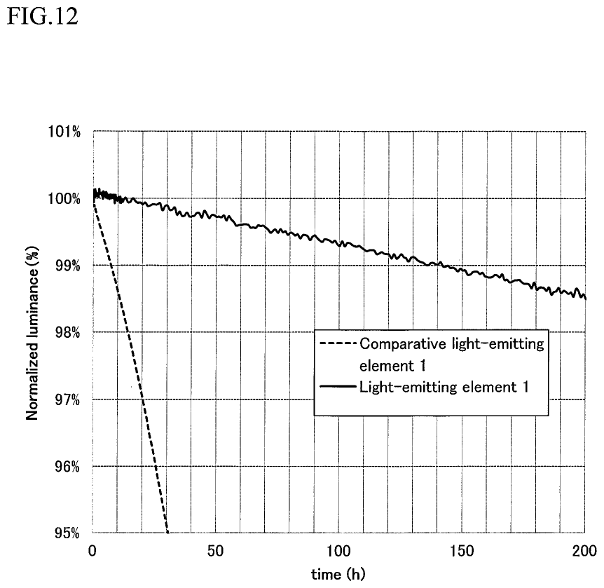

Next, a constant current drive test at a measurement temperature of 30° C. and 50 mA/cm² was conducted on the light-emitting element 1 and the comparative light-emitting element 1. FIG. 12 and Table 3 show the results of the constant current drive test.

TABLE 3
The results of the constant-current drive test

| | LT₉₅(h) |
|---|---|
| Comparative light-emitting element 1 | 31 |
| Light-emitting element 1 | 643 |

In the light emitting element 1, the time until the initial luminescence intensity decreases by 5% (LT₉₅) was shown to extend about 20 times longer than the LT₉₅ of the comparative light emitting device 1. It was thus confirmed that in the light emitting element of the embodiment of the present invention, good reliability can be obtained while maintaining high current efficiency by having a second host material in the light emitting layer.

### Example 2

The present example shows the manufacture of the light-emitting element 100 described in the first embodiment and its characteristic evaluation. Specifically, light-emitting element 2 of the embodiment of the present invention and comparative light-emitting element 2 as a comparative example were manufactured. Light-emitting element 2 is one of the light-emitting elements 100 of the first embodiment and is identical in all respects to light-emitting element 1 except for the configuration of the light-emitting layer 120 (see Table 1). Comparative light-emitting element 2 differs from light-emitting element 2 in that it does not include a second host material in the light-emitting layer. The composition of the light-emitting layer 120 of each light-emitting element is shown in Table 4.

TABLE 4
The composition of the light-emitting layer of each light-emitting element

| | Light-emitting layer | | | |
|---|---|---|---|---|
| | First host | First light- | Second host | Second light- |
| | material | emitting material | material | emitting material |
| | (vol %) | (vol %) | (vol %) | (vol %) |
| Comparative light-emitting element 2 | 49.2 | 50 | — | 0.8 |
| Light-emitting element 2 | 44.2 | 50 | 5 | 0.8 |

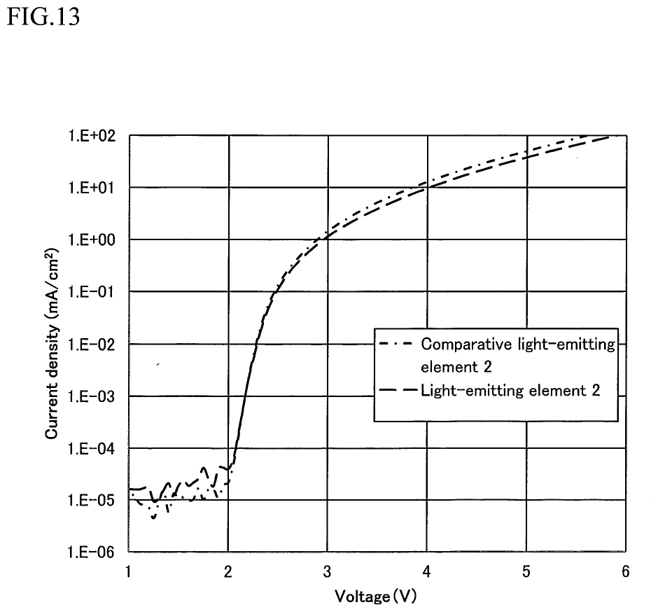

The current density-voltage properties of the light-emitting element 2 and the comparative light-emitting element 2 were measured. FIG. 13 shows the measurement results of the current density-voltage properties.

As shown in FIG. 13, the light-emitting element 2 exhibited current density-voltage properties equivalent to those of comparative light-emitting element 2 and showed high current efficiency equivalent to that of comparative light-emitting element 2. The light-emitting element 2 and comparative light-emitting element 2 exhibited green light emission. The light-emitting element 2 exhibited emission at a wavelength longer than the maximum peak wavelength of the emission spectrum exhibited by light-emitting element 1.

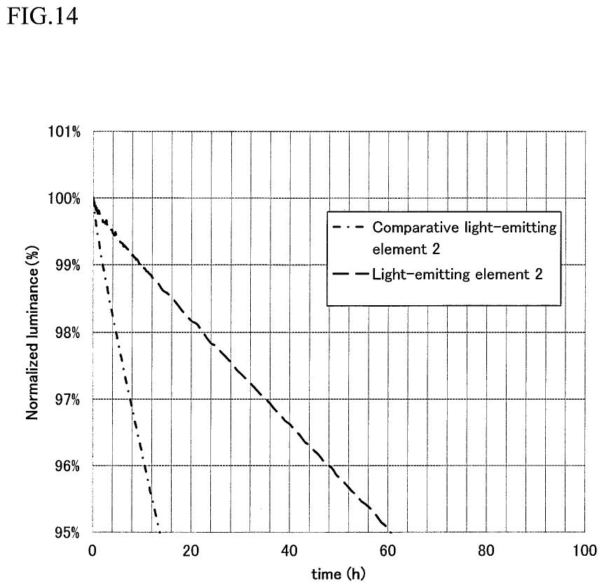

Next, constant current drive tests were conducted at a measurement temperature of 30° C. and 50 mA/cm² for the light-emitting element 2 and comparative light-emitting element 2. FIG. 14 and Table 5 show the results of the constant current drive test.

TABLE 5
The results of the constant-current drive test

| | LT₉₅(h) |
|---|---|
| Comparative light-emitting element 2 | 14 |
| Light-emitting element 2 | 61 |

In the light-emitting element 2, the time until the initial luminescence intensity decreases by 5% (LT₉₅) was shown to extend about 4 times longer than the LT₉₅ of the comparative light-emitting element 2. The results suggest that in the light-emitting element of the embodiment of the present invention, having a second host material in the light emitting layer provides good reliability while maintaining a high current efficiency.

### Example 3

The present example shows the manufacture of the light-emitting element 100 described in the First embodiment and an evaluation of its properties. Specifically, the light-emitting elements 3 to 4 of the embodiment are all identical to the light-emitting element 2, except for a different configuration of the concentration of the first light-emitting material and the concentration of the first host material in the light-emitting layer of the light-emitting element 2 (see Table 1). The comparative light-emitting elements 3 and 4, which are used as comparative examples, are identical to the light-emitting elements 3 and 4, respectively, except that the second host material is not included in the light-emitting layer. The composition of the light-emitting layers 120 of each light-emitting element is shown in Table 6.

TABLE 6
The composition of the Light-emitting layer of Light-
emitting elements of Example and Comparative example

| | Light-emitting layer | | | |
|---|---|---|---|---|
| | First host | First light- | Second host | Second light- |
| | material | emitting material | material | emitting material |
| | (vol %) | (vol %) | (vol %) | (vol %) |
| Comparative light-emitting element 3 | 59.2 | 40 | — | 0.8 |
| Comparative light-emitting element 2 | 49.2 | 50 | — | 0.8 |
| Comparative light-emitting element 4 | 39.2 | 60 | — | 0.8 |
| Light-emitting element 3 | 54.2 | 40 | 5 | 0.8 |
| Light-emitting element 2 | 44.2 | 50 | 5 | 0.8 |
| Light-emitting element 4 | 34.2 | 60 | 5 | 0.8 |

Constant current drive tests were conducted at a measured temperature of 30° C. and 50 mA/cm² for the light-emitting elements 2 to 4 and the comparative light-emitting elements 2 to 4. Table 7 shows the results of the constant current drive tests.

TABLE 7
The results of the constant-current drive test

| | LT₉₅(h) |
|---|---|
| Comparative light-emitting element 3 | 9 |
| Comparative light-emitting element 2 | 14 |
| Comparative light-emitting element 4 | 16 |
| Light-emitting element 3 | 33 |
| Light-emitting element 2 | 61 |
| Light-emitting element 4 | 117 |

The comparative light-emitting elements 2 through 4 showed improved reliability by increasing the concentration of the first light-emitting material exhibiting TADF. This is known as a means of extending the lifetime of light-emitting elements using light-emitting materials that exhibit TADF, and it is believed that TTA was promoted by increasing the concentration of the light-emitting materials in comparison to the light-emitting elements 2-4. For the light-emitting elements 2 to 4, similar to the comparative light-emitting elements 2 to 4, reliability was improved by increasing the concentration of the first light-emitting material. The results suggest that even when the light emitting elements 2 to 4 contain a second host material, the effect of increased reliability due to the increased concentration of TADF is not impaired.

### Example 4

The present example shows the manufacture and evaluation of properties of the light-emitting element 100 described in the first embodiment. Specifically, the light-emitting elements 5 to 9 of the embodiments of the present invention differ mainly in the electron mobility of the second host material and the concentration of the second host material in the light-emitting layer of the light-emitting element 1. All of the light-emitting elements 5 to 9 of the embodiments of the present invention are identical to the light-emitting element 1, except for the composition of the light-emitting layer (see Table 1). The composition of the light-emitting layers 120 of each light-emitting element is shown in Table 8.

TABLE 8
The composition of the Light-emitting layer of Light-
emitting elements of Example and Comparative example

| | Light-emitting layer | | | |
|---|---|---|---|---|
| | First host | First light- | Second host | Second light- |
| | material | emitting material | material | emitting material |
| | (vol %) | (vol %) | (vol %) | (cm²/Vs) |
| Comparative light-emitting element 1 | 50 | — | 50 | 1 × 10⁻¹¹ |
| Light-emitting element 5 | 40 | 10 | 50 | 1 × 10⁻¹¹ |
| Light-emitting element 6 | 40 | 10 | 50 | 1 × 10⁻⁹ |
| Light-emitting element 7 | 40 | 10 | 50 | 1 × 10⁻⁶ |
| Light-emitting element 1 | 45 | 5 | 50 | 1 × 10⁻¹¹ |
| Light-emitting element 8 | 45 | 5 | 50 | 1 × 10⁻⁹ |
| Light-emitting element 9 | 45 | 5 | 50 | 1 × 10⁻⁶ |

Constant current drive tests were conducted at a measured temperature of 30° C. and 50 mA/cm² for the light-emitting elements 1, 5-9 and the comparative light-emitting element 1. Table 9 shows the results of the constant current drive test.

TABLE 9
The results of the constant-current drive test

| | LT₉₅(h) |
|---|---|
| Comparative light-emitting element 1 | 31 |
| Light-emitting element 5 | 529 |
| Light-emitting element 6 | 188 |
| Light-emitting element 7 | 138 |
| Light-emitting element 1 | 643 |
| Light-emitting element 8 | 554 |
| Light-emitting element 9 | 444 |

The LT₉₅ of the light-emitting elements 1, 5-9 was shown to depend on the concentration and electron mobility of the second host material in the light-emitting layer. The results of the light-emitting elements 1, 5-9 show that good reliability can be obtained when the concentration of the second host material in the light-emitting layer is at least 5 vol % or greater and 10 vol % or less. The results of the light-emitting elements 1, 5-9 show that good reliability can be obtained when the electron mobility of the second host material is at least 1×10⁻¹¹ cm²/Vs or higher and 1×10⁻⁶ cm²/Vs or lower.

The reliability of the light-emitting elements 1, 5 to 9 improves as the concentration of the second host material in the light-emitting layer is smaller in the range of 5 vol % or greater and 10 vol % or less, and furthermore, the electron mobility of the second host material improves in the range of 1×10⁻¹¹ cm²/Vs or higher and 1×10⁻⁶ cm²/Vs or less, the lower the electron mobility of the second host material, the higher the improvement.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the light-emitting elements and display devices according to each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising:
a pair of electrodes; and
a light-emitting layer between the pair of electrodes,
wherein the light-emitting layer comprises a first host material, a second host material, a first light-emitting material exhibiting thermally activated delayed fluorescence,
a concentration of the first host material is greater than a concentration of the second host material in the light-emitting layer,
a band gap of the first host material is larger than a band gap of the second host material,
a singlet excitation energy level of the first light-emitting material is lower than a singlet excitation energy level of the first host material, and
a triplet excitation energy level of the second host material is lower than a triplet excitation energy level of the first host material.

2. The light-emitting element according to claim 1
wherein the light-emitting layer further comprises a second light-emitting material having a singlet excitation energy level lower than the singlet excitation energy level of the first light-emitting material.

3. The light-emitting element according to claim 1,
wherein the concentration of the first host material is 20 vol % or greater and 80 vol % or less in the light-emitting layer, and
the concentration of the second host material is 5 vol % or greater and 10 vol % or less in the light-emitting layer.

4. The light-emitting element according to claim 1,
wherein a concentration of the first light-emitting material is 20 vol % or greater and 60 vol % or less in the light-emitting layer.

5. The light-emitting element according to claim 1,
wherein a LUMO level of the second host material is lower than a LUMO level of the first host material.

6. The light-emitting element according to claim 1,
wherein a triplet excitation energy level of the first light-emitting material is lower than the triplet excitation energy level of the first host material.

7. The light-emitting element according to claim 1,
wherein the triplet excitation energy level of the second host material is lower than a triplet excitation energy level of the first light-emitting material.

8. The light-emitting element according to claim 2,
wherein an emission color of the second light-emitting material is between green and red.

9. The light-emitting element according to claim 1,
wherein an electron mobility of the second host material is 1×10⁻¹¹ cm²/Vs or higher and 1×10⁻⁶ cm²/Vs or lower.

10. The light-emitting element according to claim 1,
wherein an emission color of the first light-emitting material is between green and yellow.

11. A display device comprising:
a first pixel having a first light-emitting element; and
a second pixel having a second light-emitting element,
wherein the first light-emitting element has a pair of electrodes, and a first light-emitting layer between the pair of electrodes,
the first light-emitting layer comprises a first host material, a second host material, and a first light-emitting material exhibiting thermally activated delayed fluorescence,
the second light-emitting element has the pair of electrodes, and a second light-emitting layer between the pair of electrodes,
the second light-emitting layer comprises the second host material, and a second light-emitting material having a singlet excitation energy level higher than a singlet excitation energy level of the first light-emitting material,
a concentration of the first host material is greater than a concentration of the second host material in the first light-emitting layer,
a band gap of the first host material is larger than a band gap of the second host material, and
a triplet excitation energy level of the second host material is lower than a triplet excitation energy level of the first host material.

12. The display device according to claim 11,
wherein the first emitting layer further comprises a third light-emitting material having a singlet excitation energy level lower than a singlet excitation energy level of the first light-emitting material.

13. The display device according to claim 11,
wherein the concentration of the first host material is 20 vol % or greater and 80 vol % or less in the first light-emitting layer, and
a concentration of the second host material is 5 vol % or greater and 10 vol % or less in the first light-emitting layer.

14. The display device according to claim 11,
wherein the concentration of the first light-emitting material is 20 vol % or greater and 60 vol % or less in the first light-emitting layer.

15. The display device according to claim 11,
wherein a LUMO level of the second host material is lower than a LUMO level of the first host material.

16. The display device according to claim 11,
wherein a triplet excitation energy level of the first light-emitting material is lower than the triplet excitation energy level of the first host material.

17. The display device according to claim 11,
wherein the triplet excitation energy level of the second host material is lower than a triplet excitation energy level of the first light-emitting material.

18. The display device according to claim 11,
wherein an electron mobility of the second host material is 1×10⁻¹¹ cm²/Vs or higher and 1×10⁻⁶ cm²/Vs or lower.

19. The display device according to claim 11,
wherein an emission color of the first light-emitting material is between green and yellow.

20. The display device according to claim 11, wherein an emission color of the second light-emitting material is blue.
